(19) United States
(12) Patent Application Publication
(10) Pub. No.: US 2007/0013443 A1
(43) Pub. Date: Jan. 18, 2007

(54) Compartmental gain limiter and controlling method thereof

(75) Inventor: Chih-Hui Tien, Taipei (TW)

Correspondence Address: RABIN & Berdo, PC, 1101 14TH STREET, NW, SUITE 500, WASHINGTON, DC, 20005, US

(73) Assignee: ASUSTek COMPUTER INC.

(21) Appl. No.: 11/483,631

(22) Filed: Jul. 11, 2006

(30) Foreign Application Priority Data
Jul. 15, 2005 (TW) 94124204

(51) Int. Cl. H03F 1/36

(52) U.S. Cl. 330/86; 327/312

(57) ABSTRACT

A compartmental gain limiter and a controlling method thereof. The compartmental gain limiter connects to an audio amplifier, which has a gain value and generates an output signal according to an input signal and the gain value. The compartmental gain limiter includes a comparator and a clamper. The comparator having a critical value receives the output signal and outputs a driven signal when the output signal is greater than the critical value. The clamper receives the driven signal and outputs a control signal according to the driven signal so as to clamp the output signal via the audio amplifier.

This application claims the benefit of Taiwan application Serial No. 94124204, filed Jul. 15, 2005, the subject matter of which is incorporated herein by reference.

### BACKGROUND OF THE INVENTION

1. Field of the Invention

The invention relates in general to a compartmental gain limiter and a controlling method thereof, and more particularly to a compartmental gain limiter for an audio amplifier and a controlling method thereof.

2. Description of the Related Art

As the electronic technology is advanced to the multimedia age, personal computers, notebook computers, video disc players and digital audio players are designed in a multi-functional trend. For example, the personal computer, the video disc player, or the notebook computer often serve as a video/audio player, and the user also expects the personal computer, the video disc player or the notebook computer serving as the video/audio player to have a better video/audio playing effect. The speaker in the current notebook computer has the specification of 8 Ω/1W, and the maximum with standing input voltage is 2.828Vrms (the maximum voltage is 4V), which is higher than the output power of the typical mobile player. In the practical application, the power connected to the audio amplifier of the notebook computer is 5V, so the voltage outputted to the speaker may exceed 4V and thus burns out the speaker. Thus, the engineer reduces the voltage gain of the audio amplifier so as to prevent the speaker from burning out. However, while the voltage gain is reduced, the actual output power of the audio is insufficient. For example, even if the volume of the speaker of the notebook computer is adjusted to the maximum, the shock effect generated by the mobile player still cannot be obtained.

FIG. 1A is a circuit diagram showing an inverting amplifier in a conventional audio amplifier. Referring to FIG. 1A, an inverting amplifier 100 includes an OP amplifier 110, a resistor R1 and a resistor R2. An external power 160 provides a DC operation voltage Vcc for the OP amplifier 110. The gain value of the inverting amplifier is

$$\frac{- R 2}{R 1} .$$

The inverting amplifier 100 amplifies an AC input voltage V1 according to the gain value and then outputs an AC output voltage V1′, wherein

$$V {1}^{′} = \frac{- R 2}{R 1} \times V 1.$$

FIG. 1B is a circuit diagram showing a noninverting amplifier in the conventional audio amplifier. Referring to FIG. 1B, a noninverting amplifier 200 includes an OP amplifier 110, a resistor R3, a resistor R4, a resistor R5 and a resistor R6. An external power 160 provides a DC operation voltage Vcc for the OP amplifier 110. The gain value of the noninverting amplifier is

$$\frac{R 5}{R 5 + R 6} \times \frac{R 3 + R 4}{R 3} .$$

The noninverting amplifier 200 amplifies an AC input voltage V2 according to the gain value and then outputs an AC output voltage V2′, wherein

$$V {2}^{′} = \frac{R 5}{R 5 + R 6} \times \frac{R 3 + R 4}{R 3} \times V 2.$$

The maximum amplitudes of the AC output voltage V1′ of the inverting amplifier 100 (FIG. 1A) and the AC output voltage V2′ of the noninverting amplifier 200 (FIG. 1B) are determined according to the DC operation voltage Vcc of the OP amplifier 110, and the AC output voltages V1′ (FIG. 1A) and V2′ (FIG. 1B) have to be applied to a speaker 190 such that the acoustic effect can be generated. So, it is to be particularly noted that whether the amplitude of the AC output voltage V1′ or V2′ exceeds the loading of the speaker 190 or not. As mentioned hereinabove, the speaker used in the notebook computer typically has the specification of 8 Ω/1W, so the peak-to-peak value (Vp-p) of the AC output voltage V1′ or V2′ that can be withstood by the speaker 190 is about 4V. Furthermore, the DC operation voltage provided in the notebook computer is 5V. So, when the AC output voltage V1′ or V2′ generated after the AC input voltage V1 or V2 is amplified is greater than 4V, the speaker 190 tends to burn out because it cannot withstand the loading.

In order to prevent the speaker 190 from burning out, the gain value of the audio amplifier or the AC input voltage of the audio amplifier has to be reduced according to a maximum amplitude Vomax of the AC output voltage that can be withstood by the speaker 190, such that the amplitude of the AC output voltage V1′ or V2′ is clamped. However, while the gain value is being reduced, the original output volume of the speaker 190 is sacrificed, and the overall acoustic effect is reduced.

FIG. 2A is a circuit diagram showing the inverting amplifier with an added DC voltage transformer. FIG. 2B is a circuit diagram showing the noninverting amplifier with an added DC voltage transformer. Referring to FIGS. 2A and 2B, another method for clamping the amplitudes of the AC output voltages V1′ and V2′ of the OP amplifier 110 is to reduce the DC operation voltage Vcc of the OP amplifier 110 in order to prevent the speaker 190 from burning out and to make the DC operation voltage Vcc equal the maximum amplitude Vomax of the AC output voltage that can be withstood by the speaker 190. Because the maximum amplitude Vomax of the AC output voltage of the OP amplifier 110 equals the DC operation voltage Vcc of the OP amplifier 110 and the DC operation voltage Vcc of the conventional OP amplifier 110 is directly provided by the external power 160, the object of clamping the amplitude of the AC output voltage of the OP amplifier 110 may be achieved by adding a DC voltage transformer 170 to adjust the voltage of the external power 160 to be equal to the maximum amplitude Vomax of the AC output voltage that can be withstood by the speaker 190.

However, adding the DC voltage transformer 170 has to enlarge the area of the printed circuit board and thus increase the manufacturing cost. In addition, the added DC voltage transformer 170 occupies the space in the original system, and EMI (Electro Magnetic Interference) may occur to interfere with the normal operation of the electronic product.

### SUMMARY OF THE INVENTION

It is therefore an object of the invention to provide a compartmental gain limiter. The compartmental gain limiter of the invention can amplify an AC input voltage according to an original gain value of an audio amplifier and then output an AC output voltage when an amplitude of the AC output voltage of the audio amplifier does not reach a maximum amplitude of the AC output voltage, which can be withstood by a speaker. Thus, the actual audio output power can make the speaker keep the original sound field shock effect. When the AC output voltage approximates the maximum amplitude of the AC output voltage that can be withstood by the speaker, the compartmental gain limiter clamps the AC input voltage or the gain value of the audio amplifier so as to protect the speaker from burning out by the too-high AC output voltage.

The invention achieves the above-identified object by providing a compartmental gain limiter to be connected to an audio amplifier, which has a gain value and outputs an output signal according to an input signal and the gain value. The compartmental gain limiter includes a comparator and a clamper. The comparator has a critical value. The comparator detects the output signal of the audio amplifier, and outputs a driven signal when the output signal of the audio amplifier is greater than the critical value of the comparator. The clamper receives the driven signal and outputs a control signal, according to the driven signal, to control the audio amplifier to clamp the output signal.

The invention also achieves the above-identified object by providing a method of controlling a compartmental gain limiter, which is connected to an audio amplifier. The compartmental gain limiter includes a comparator and a clamper. The method includes the steps of: utilizing the comparator to detect an output signal of the audio amplifier; judging whether the output signal is greater than a critical value of the comparator; outputting a driven signal when the output signal is greater than the critical value; driving the clamper to output a control signal according to the driven signal; and controlling the audio amplifier to clamp the output signal according to the control signal.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a circuit diagram showing an inverting amplifier in a conventional audio amplifier.

FIG. 1B is a circuit diagram showing a noninverting amplifier in the conventional audio amplifier.

FIG. 2A is a circuit diagram showing the inverting amplifier with an added DC voltage transformer.

FIG. 2B is a circuit diagram showing the noninverting amplifier with an added DC voltage transformer.

FIG. 3 is a block diagram showing a compartmental gain limiter of the invention, which is connected to an audio amplifier.

FIG. 4A is a schematic illustration showing a compartmental gain limiter connected to an inverting amplifier according to a first embodiment of the invention.

FIG. 4B is a schematic illustration showing a compartmental gain limiter connected to an inverting amplifier according to a second embodiment of the invention.

FIG. 4C is a schematic illustration showing a compartmental gain limiter connected to an inverting amplifier according to a third embodiment of the invention.

FIG. 5A is a schematic illustration showing a compartmental gain limiter connected to an inverting amplifier according to a fourth embodiment of the invention.

FIG. 5B is a schematic illustration showing a compartmental gain limiter connected to an inverting amplifier according to a fifth embodiment of the invention.

FIG. 5C is a schematic illustration showing a compartmental gain limiter connected to an inverting amplifier according to a sixth embodiment of the invention.

FIG. 6A is a schematic illustration showing a compartmental gain limiter connected to a noninverting amplifier according to a seventh embodiment of the invention.

FIG. 6B is a schematic illustration showing a compartmental gain limiter connected to a noninverting amplifier according to an eighth embodiment of the invention.

FIG. 6C is a schematic illustration showing a compartmental gain limiter connected to a noninverting amplifier according to a ninth embodiment of the invention.

FIG. 7A is a schematic illustration showing a compartmental gain limiter connected to a noninverting amplifier according to a tenth embodiment of the invention.

FIG. 7B is a schematic illustration showing a compartmental gain limiter connected to a noninverting amplifier according to an eleventh embodiment of the invention.

FIG. 7C is a schematic illustration showing a compartmental gain limiter connected to a noninverting amplifier according to a twelfth embodiment of the invention.

FIG. 8 is a circuit diagram showing a compartmental gain limiter connected to an inverting amplifier according to a thirteenth embodiment of the invention.

FIG. 9A shows measured waveforms when an AC output voltage of the conventional inverting amplifier does not reach a critical value.

FIG. 9B shows measured waveforms when an AC output voltage of the invention does not reach a critical value.

FIG. 9C shows measured waveforms when the AC output voltage of the conventional inverting amplifier exceeds the critical value.

FIG. 9D shows measured waveforms when the AC output voltage of the invention exceeds the critical value.

FIG. 10 is a flow chart showing a method of the compartmental gain limiter for controlling the audio amplifier according to a preferred embodiment of the invention.

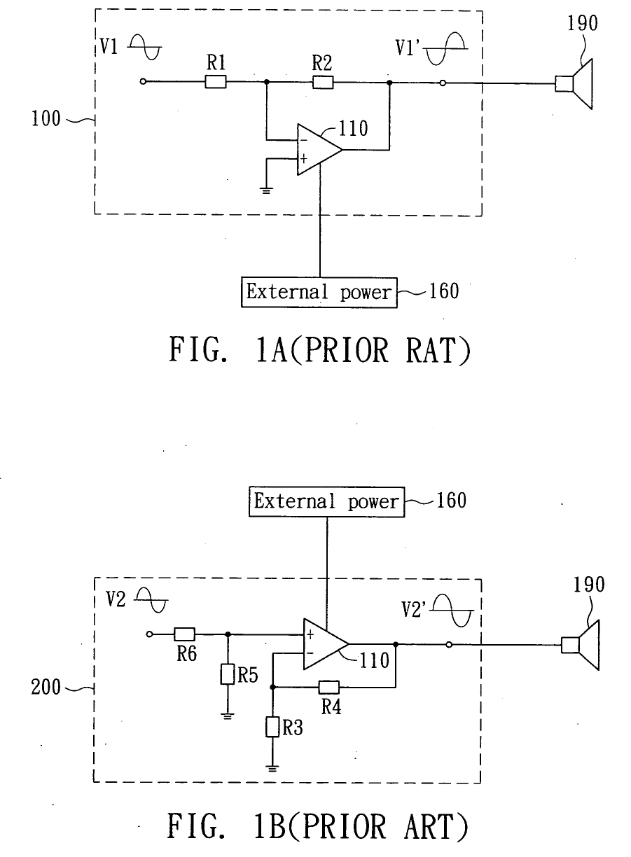

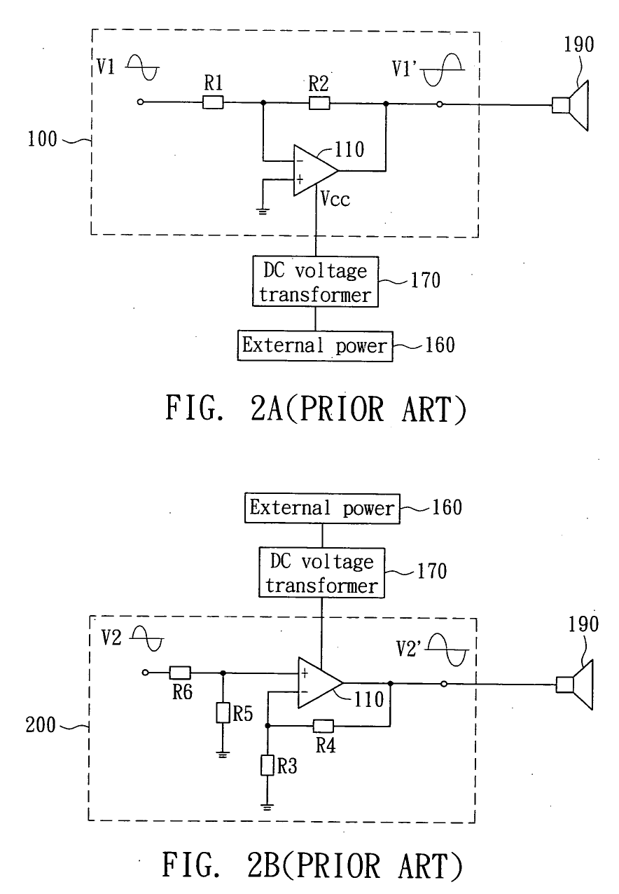

### DETAILED DESCRIPTION OF THE INVENTION

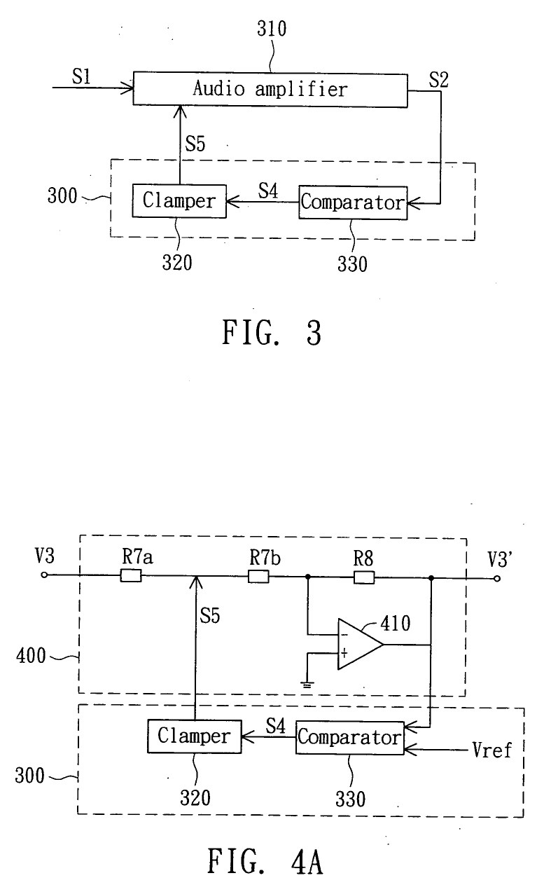

FIG. 3 is a block diagram showing a compartmental gain limiter of the invention, which is connected to an audio amplifier. Referring to FIG. 3, a compartmental gain limiter 300 is connected to an audio amplifier 310, which may be, for example, an inverting amplifier or a noninverting amplifier. The audio amplifier 310 amplifies an input signal S1 according to a gain value and then outputs an output signal S2. The compartmental gain limiter 300 includes a comparator 330 and a clamper 320. The comparator 330 receives the output signal S2 of the audio amplifier 310. When the output signal S2 of the audio amplifier 310 is greater than a critical value of the comparator 330, the comparator 330 outputs a driven signal S4. The clamper 320 outputs a control signal S5 according to the driven signal S4 of the comparator 330. The compartmental gain limiter 300 controls the input signal S1 or the gain value of audio amplifier 310 according to the control signal S5 so as to clamp the output signal S2 of the audio amplifier 310. According to the design of the compartmental gain limiter 300 of the invention, the problems of decreasing the overall output power and influencing the original sound field shock effect of a speaker, which occur in the conventional audio amplifier when the original voltage gain of the audio amplifier 310 is sacrificed in order to prevent the speaker from burning out, may be effectively solved.

### First Embodiment

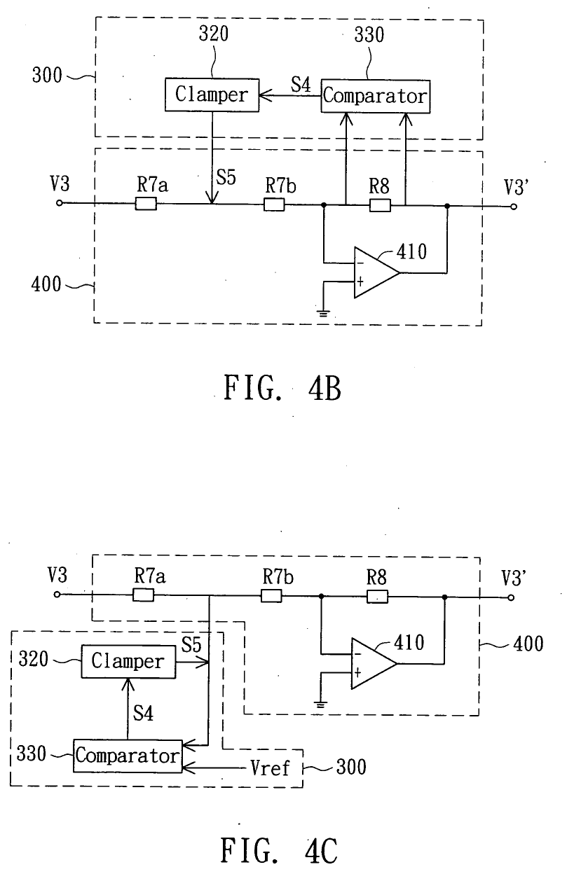

FIG. 4A is a schematic illustration showing a compartmental gain limiter connected to an inverting amplifier according to a first embodiment of the invention. In detail, the audio amplifier is an inverting amplifier 400 in one embodiment. The inverting amplifier 400 includes a resistor R7a, a resistor R7b, a resistor R8 and an OP amplifier 410. A second terminal of the resistor R7a is electrically connected to a first terminal of the resistor R7b. A second terminal of the resistor R7b and a first terminal of the resistor R8 are electrically connected to an inverting input terminal of the OP amplifier 410. A second terminal of the resistor R8 is electrically connected to an output terminal of the OP amplifier 410. A noninverting input terminal of the OP amplifier 410 is grounded. The gain value of the inverting amplifier 400 is determined according to the resistor R7a, the resistor R7b and the resistor R8.

When an input signal of the inverting amplifier 400 is an AC input voltage V3 and enters the inverting amplifier 400 through the first terminal of the resistor R7a, the inverting amplifier 400 amplifies the AC input voltage V3 according to the gain value and then outputs an output signal, such as an AC output voltage V3′, to the comparator 330 of the compartmental gain limiter 300. The critical value of the comparator 330 may be a reference voltage Vref. When the AC output voltage V3′ is greater than the reference voltage Vref, the comparator 330 outputs a driven signal S4. The clamper 320 outputs a control signal S5 according to the driven signal S4 so as to control the voltage of the inverting input terminal of the OP amplifier 410 and thus to clamp the AC output voltage V3′.

### Second Embodiment

The output signal received by the comparator 330 of the compartmental gain limiter 300 may be the AC output voltage V3′ or the potential difference between two terminals of the resistor R8, for example. FIG. 4B is a schematic illustration showing a compartmental gain limiter connected to an inverting amplifier according to a second embodiment of the invention. Referring to FIG. 4B, the comparator 330 of the compartmental gain limiter 300 compares the potential difference between the two terminals of the resistor R8 with the reference voltage (not shown) of the comparator 330. When the potential difference between the two terminals of the resistor R8 is greater than the reference voltage of the comparator 330, the comparator 330 outputs a driven signal S4. The clamper 320 outputs a control signal S5 according to the driven signal S4 so as to control the voltage of the inverting input terminal of the OP amplifier 410 and thus to clamp the AC output voltage V3′.

### Third Embodiment

FIG. 4C is a schematic illustration showing a compartmental gain limiter connected to an inverting amplifier according to a third embodiment of the invention. Similarly, the output signal may also be the potential difference between two terminals of the resistor R7b. The comparator 330 of the compartmental gain limiter 300 compares the potential difference between the two terminals of the resistor R7b with the reference voltage Vref. When the potential difference between the two terminals of the resistor R7b is greater than the reference voltage Vref, the comparator 330 outputs a driven signal S4. The clamper 320 outputs a control signal S5 according to the driven signal S4 so as to control the voltage of the inverting input terminal of the OP amplifier 410 and thus to clamp the AC output voltage V3′.

### Fourth Embodiment

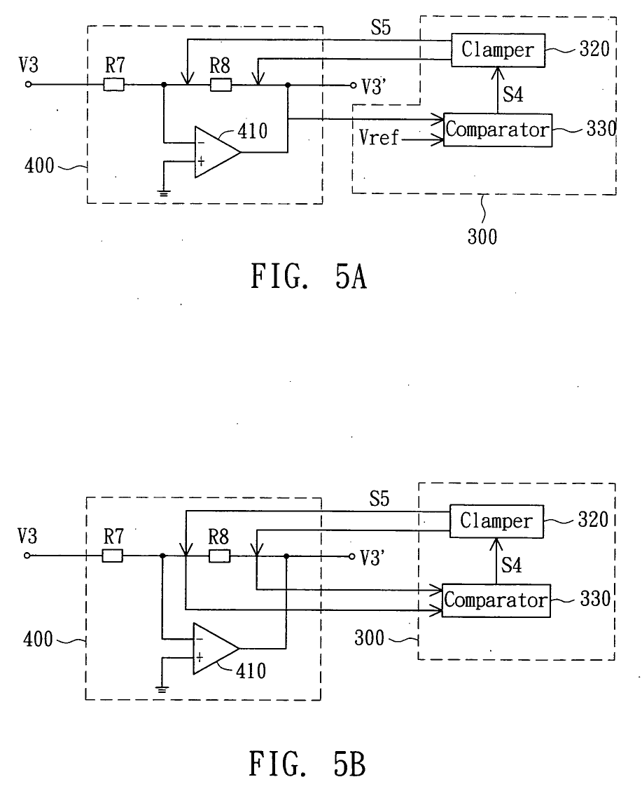

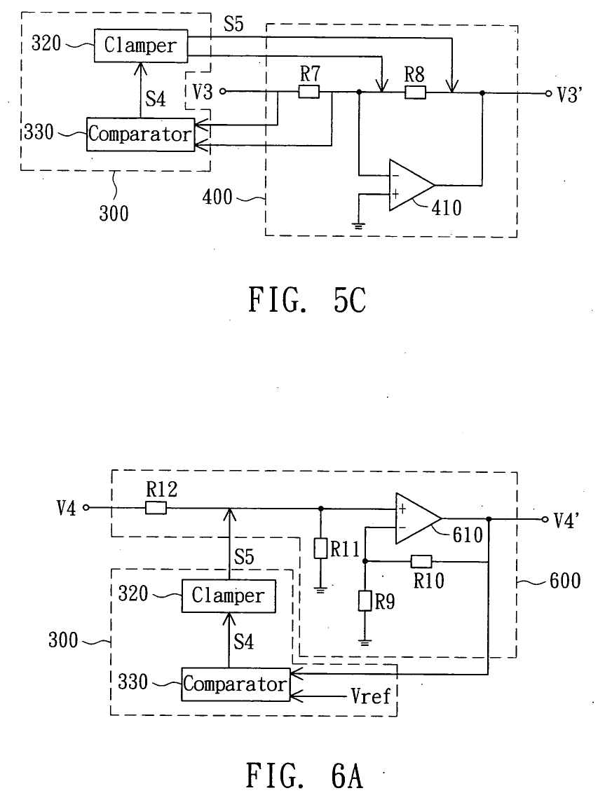

The clamper 320 of the compartmental gain limiter 300 outputs a control signal S5 according to the driven signal S4. The control signal S5 of the clamper 320 can control the voltage of the inverting input terminal of the OP amplifier 410. In addition, the clamper 320 may also be configured such that the clamper 320 can change the resistance of the resistor R8 according to the control signal S5 so as to control the gain value of the inverting amplifier 400. FIG. 5A is a schematic illustration showing a compartmental gain limiter connected to an inverting amplifier according to a fourth embodiment of the invention. Referring to FIG. 5A, the comparator 330 of the compartmental gain limiter 300 compares the output signal of the inverting amplifier 400 with the reference voltage Vref, wherein the output signal may be, for example, the AC output voltage V3′. When the AC output voltage V3′ of the inverting amplifier 400 is greater than the reference voltage Vref of the comparator 330, the comparator 330 outputs a driven signal S4. The clamper 320 outputs a control signal S5 according to the driven signal S4. The clamper 320 changes the resistance of the resistor R8 according to the control signal S5 so as to control the gain value of the inverting amplifier 400 and thus to clamp the AC output voltage V3′.

### Fifth Embodiment

The output signal received by the comparator 330 of the compartmental gain limiter 300 may be the AC output voltage V3′ or the potential difference between two terminals of the resistor R8. FIG. 5B is a schematic illustration showing a compartmental gain limiter connected to an inverting amplifier according to a fifth embodiment of the invention. Referring to FIG. 5B, the comparator 330 compares the potential difference between the two terminals of the resistor R8 with the reference voltage (not shown in FIG. 5B) of the comparator 330. When the potential difference between the two terminals of the resistor R8 is greater than the reference voltage, the comparator 330 outputs a driven signal S4. The clamper 320 outputs a control signal S5 according to the driven signal S4. The clamper 320 changes the resistance of the resistor R8 according to the control signal S5 so as to control the gain value of the inverting amplifier 400 and thus to clamp the AC output voltage V3′.

### Sixth Embodiment

FIG. 5C is a schematic illustration showing a compartmental gain limiter connected to an inverting amplifier according to a sixth embodiment of the invention. Similarly, the output signal may also be the potential difference between two terminals of the resistor R7. The comparator 330 of the compartmental gain limiter 300 may also compare the potential difference between the two terminals of the resistor R7 with the reference voltage (not shown) of the comparator 330. When the potential difference between the two terminals of the resistor R7 is greater than the reference voltage, the comparator 330 outputs a driven signal S4. The clamper 320 outputs a control signal S5 according to the driven signal S4. The clamper 320 changes the resistance of the resistor R8 according to the control signal S5 so as to control the gain value of the inverting amplifier 400 and thus to clamp the AC output voltage V3′.

### Seventh Embodiment

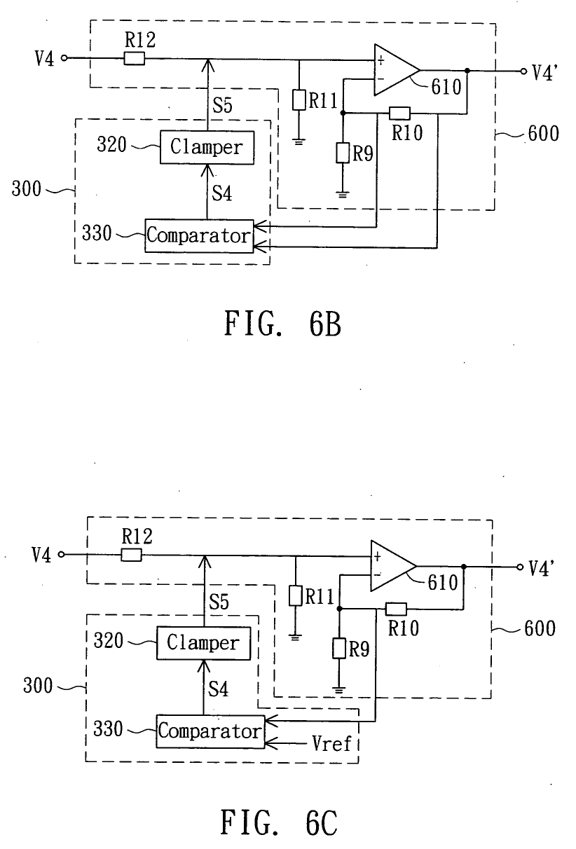

In addition to the inverting amplifier, the invention may also use the noninverting amplifier. FIG. 6A is a schematic illustration showing a compartmental gain limiter connected to a noninverting amplifier according to a seventh embodiment of the invention. As shown in FIG. 6A, the audio amplifier may be a noninverting amplifier 600. The noninverting amplifier 600 includes a resistor R9, a resistor R10, a resistor R11, a resistor R12 and an OP amplifier 610. The second terminal of the resistor R12 and the first terminal of the resistor R11 are electrically connected to the noninverting input terminal of the OP amplifier 610. The second terminal of the resistor R11 is grounded. The first terminal of the resistor R9 and the first terminal of the resistor R10 are electrically connected to the inverting input terminal of the OP amplifier 610. The second terminal of the resistor R9 is grounded. The second terminal of the resistor R10 is electrically connected to the output terminal of the OP amplifier 610. The gain value of the noninverting amplifier 600 is determined according to the resistor R9, the resistor R10, the resistor R11 and the resistor R12.

When the input signal of the noninverting amplifier 600 is an AC input voltage V4 and enters the noninverting amplifier 600 through the first terminal of the resistor R12, the noninverting amplifier 600 amplifies the AC input voltage V4 according to the gain value and then outputs an output signal to the comparator 330. The output signal may be, for example, an AC output voltage V4′. The critical value of the comparator 330 may be a reference voltage Vref. When the AC output voltage V4′ is greater than the reference voltage Vref, the comparator 330 outputs a driven signal S4. The clamper 320 outputs a control signal S5 according to the driven signal S4 so as to control the voltages between two terminals of the resistor R11 and thus to clamp the AC output voltage V4′.

### Eighth Embodiment

The output signal received by the comparator 330 of the compartmental gain limiter 300 may be an AC output voltage V4′ or a potential difference between two terminals of the resistor R10. FIG. 6B is a schematic illustration showing a compartmental gain limiter connected to a noninverting amplifier according to an eighth embodiment of the invention. Referring to FIG. 6B, a comparator 330 of the compartmental gain limiter 300 compares the potential difference between the two terminals of the resistor R10 with the reference voltage (not shown). When the potential difference between the two terminals of the resistor R10 is greater than the reference voltage, the comparator 330 outputs a driven signal S4. The clamper 320 outputs a control signal S5 according to driven signal S4 so as to control the voltages between the two terminals of the resistor R11 and thus to clamp AC output voltage V4′.

### Ninth Embodiment

FIG. 6C is a schematic illustration showing a compartmental gain limiter connected to a noninverting amplifier according to a ninth embodiment of the invention. Similarly, the output signal may also be the potential difference between two terminals of the resistor R9. The comparator 330 may also compare the potential difference between the two terminals of the resistor R9 with the reference voltage Vref. When the potential difference between the two terminals of the resistor R9 is greater than the reference voltage Vref, the comparator 330 outputs a driven signal S4. The clamper 320 outputs a control signal S5 according to the driven signal S4 so as to control the voltages between the two terminals of the resistor R11 and thus to clamp the AC output voltage V4′.

### Tenth Embodiment

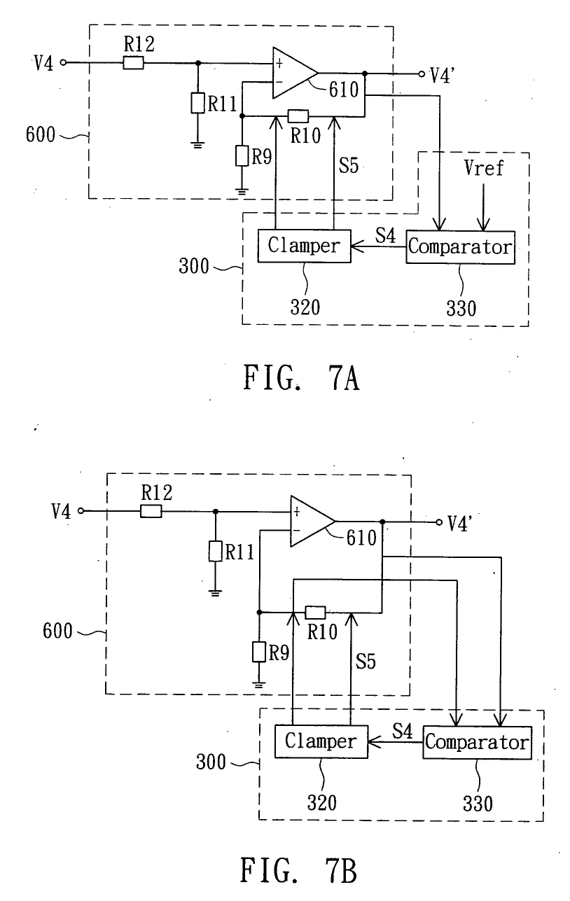

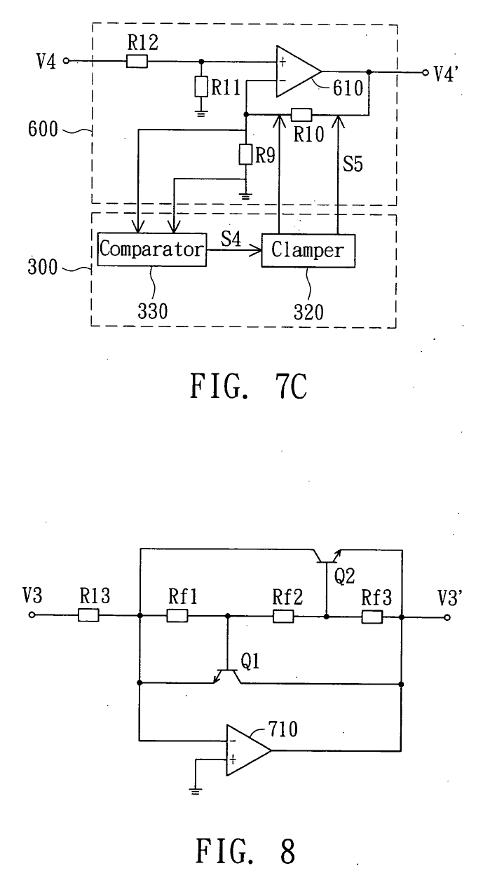

The clamper 320 of the compartmental gain limiter 300 outputs a control signal S5 according to the driven signal S4 so as to control the voltages between the two terminals of the resistor R10. In addition, the clamper 320 may also be configured such that the clamper 320 can change the resistance of the resistor R10 according to the control signal S5 so as to control the gain value of the noninverting amplifier 600. FIG. 7A is a schematic illustration showing a compartmental gain limiter connected to a noninverting amplifier according to a tenth embodiment of the invention. Referring to FIG. 7A, the comparator 330 of the compartmental gain limiter 300 compares the output signal of the noninverting amplifier 600 with the reference voltage Vref, wherein the output signal may be the AC output voltage V4′, for example. When the AC output voltage V4′ of the noninverting amplifier 600 is greater than the reference voltage Vref of the comparator 330, the comparator 330 outputs a driven signal S4. The clamper 320 of the compartmental gain limiter 300 outputs a control signal S5 according to the driven signal S4. The clamper 320 can change the resistance of the resistor R10 according to the control signal S5 so as to control the gain value of the noninverting amplifier 600 and thus to clamp the AC output voltage V4′.

### Eleventh Embodiment

The output signal received by the comparator 330 may be the AC output voltage V4′ or the potential difference between two terminals of the resistor R10, for example. FIG. 7B is a schematic illustration showing a compartmental gain limiter connected to a noninverting amplifier according to an eleventh embodiment of the invention. Referring to FIG. 7B, the comparator 330 compares the potential difference between the two terminals of the resistor R10 with the reference voltage (not shown) of the comparator 330. When the potential difference between the two terminals of the resistor R10 is greater than the reference voltage, the comparator 330 outputs a driven signal S4. The clamper 320 outputs a control signal S5 according to the driven signal S4. The clamper 320 can change the resistance of the resistor R10 according to the control signal S5 so as to control the gain value of the noninverting amplifier 600 and thus to clamp the AC output voltage V4′.

### Twelfth Embodiment

FIG. 7C is a schematic illustration showing a compartmental gain limiter connected to a noninverting amplifier according to a twelfth embodiment of the invention. Similarly, the output signal may also be the potential difference between two terminals of the resistor R9, for example. The comparator 330 of the compartmental gain limiter 300 may also compare the potential difference between the two terminals of the resistor R9 with the reference voltage (not shown) of the comparator 330. When the potential difference between the two terminals of the resistor R9 is greater than the reference voltage, the comparator 330 outputs a driven signal S4. The clamper 320 outputs a control signal S5 according to the driven signal S4. The clamper 320 can change the resistance of the resistor R10 according to the control signal S5 so as to control the gain value of the noninverting amplifier 600 and thus to clamp the AC output voltage V3′.

### Thirteenth Embodiment

FIG. 8 is a circuit diagram showing a compartmental gain limiter connected to an inverting amplifier according to a thirteenth embodiment of the invention. Referring to FIG. 8, the circuit of the thirteenth embodiment includes an OP amplifier 710, a resistor R13, a resistor Rf1, a resistor Rf2, a resistor Rf3, a first transistor Q1 and a second transistor Q2. This embodiment utilizes the cut-in voltage at the base-emitter junction of the first transistor Q1 and the second transistor Q2 as a reference voltage of the comparator 330, and utilizes the voltages of the collector and the emitter of the first transistor Q1 and the second transistor Q2 as the clamper 320. Meanwhile, the resistor Rf1 and the resistor Rf3 have substantially the same resistance so that the outputs of the first transistor Q1 and the second transistor Q2 are clamped when the positive half cycle and the negative half cycle of the AC output voltage exceed the reference voltage.

The second terminal of the resistor R13, the first terminal of the resistor Rf1, the emitter of the first transistor Q1 and the collector of the second transistor Q2 are electrically connected to the inverting input terminal of the OP amplifier 710. The second terminal of the resistor Rf1 and the first terminal of the resistor Rf2 are electrically connected to the base of the first transistor Q1. The second terminal of the resistor Rf2 and the first terminal of the resistor Rf3 are electrically connected to the base of the second transistor Q2. The second terminal of the resistor Rf3, the collector of the first transistor Q1 and the emitter of the second transistor Q2 are electrically connected to the output terminal of the OP amplifier. The noninverting input terminal of the OP amplifier 710 is grounded.

After the AC input voltage V3 is inputted, if the potential difference between two terminals of the resistor Rf1 or the potential difference between two terminals of the resistor Rf2 is smaller than the reference voltage, which is the threshold voltage of the transistor in this embodiment, the first transistor Q1 and the second transistor Q2 are still at the cut-off state, and the circuit outputs the AC output voltage

$$V {3}^{′} = - \frac{Rf 1 + Rf 2 + Rf 3}{R 13} \times V 3$$

according to the AC input voltage V3.

After the AC input voltage V3 is inputted, if the potential difference between the two terminals of the resistor Rf1 or the potential difference between the two terminals of the resistor Rf2 is greater than the reference voltage, the first transistor Q1 and the second transistor Q2 are not at the original cut-off state, and the current at the base of the first transistor Q1 or the second transistor Q2 starts to increase. Thus, the current flowing through the first feedback resistor Rf1, the second feedback resistor Rf2 or the third feedback resistor Rf3 is correspondingly reduced. At this time, the circuit determines the AC output voltage V3′ according to the current flowing through the resistor and the resistances of the resistor Rf1, the resistor Rf2 and the resistor Rf3.

The circuit of the embodiment can clamp the AC output voltage according the cut-in voltage at the base-emitter junction of the transistor. This embodiment can have the function of temperature compensation according to the property that the cut-in voltage at the base-emitter junction of the transistor is inversely proportional to the temperature.

However, the invention does not intend to limit itself to the usage of the transistor to achieve the function of the comparator. Instead, the function of this embodiment may be achieved according to the circuit layout of the OP amplifier.

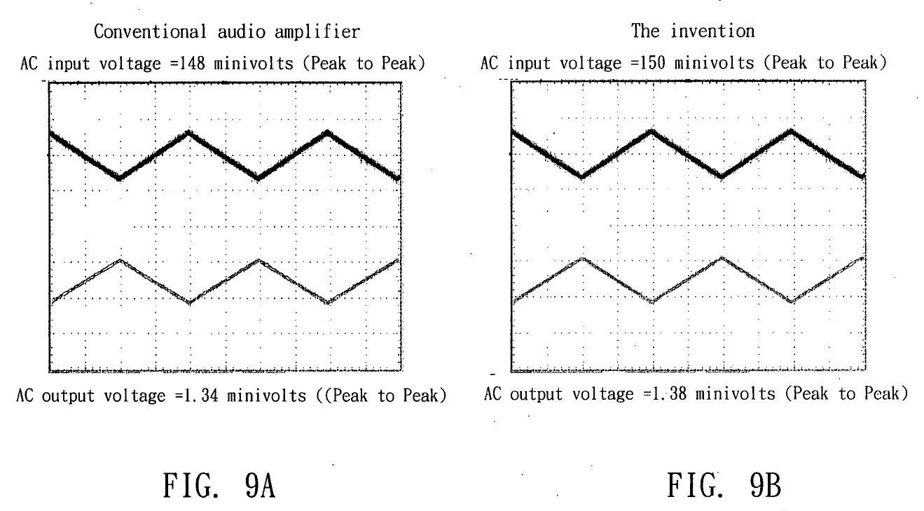

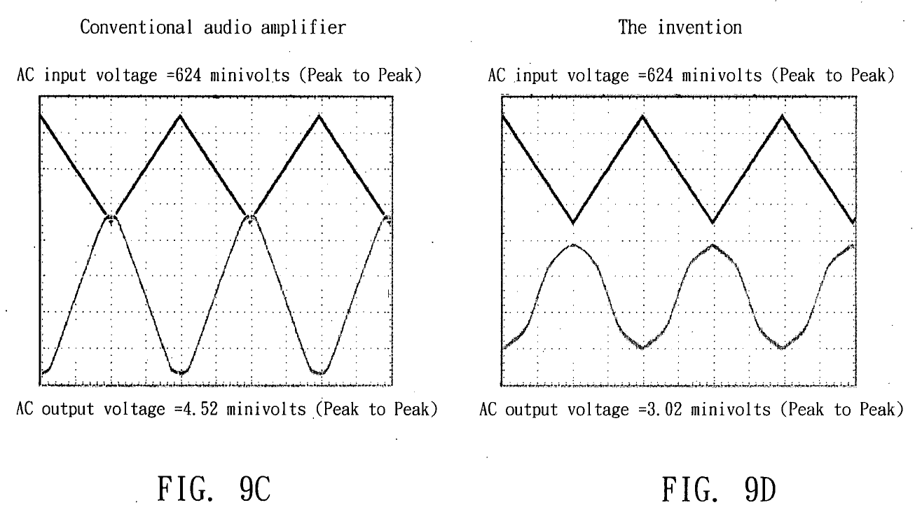

FIG. 9A shows measured waveforms when an AC output voltage of the conventional inverting amplifier does not reach a critical value. FIG. 9B shows measured waveforms when an AC output voltage of the invention does not reach a critical value. As shown in FIGS. 9A and 9B, when the AC output voltage of the inverting amplifier does not reach the critical value of the comparator, the AC output voltage of the invention and the AC output voltage of the conventional inverting amplifier are amplified according to the original gain value of the inverting amplifier and then outputted.

FIG. 9C shows measured waveforms when the AC output voltage of the conventional inverting amplifier exceeds the critical value. FIG. 9D shows measured waveforms when the AC output voltage of the invention exceeds the critical value. As shown in FIGS. 9C and 9D, when the AC output voltage of the inverting amplifier exceeds the critical value of the comparator, the conventional inverting amplifier still amplifies the AC input voltage according to the original gain value and the speaker cannot withstand the too-great load and burns out. When the AC output voltage of the inverting amplifier of the invention exceeds the critical value of the comparator, the invention clamps the AC output voltage within the loading range that can be withstood by the speaker so as to protect the speaker from burning out.

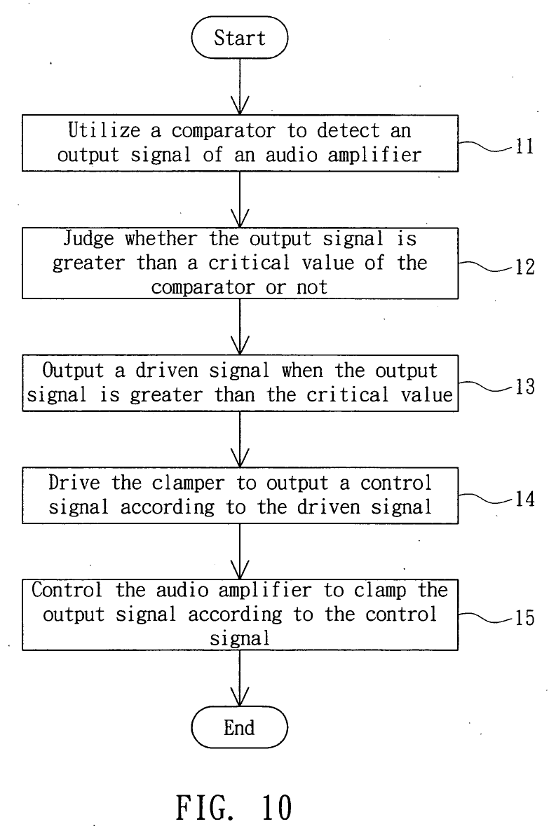

FIG. 10 is a flow chart showing a method of the compartmental gain limiter for controlling the audio amplifier according to a preferred embodiment of the invention. Referring to FIG. 10, the method of controlling the compartmental gain limiter includes the following steps. First, step 11 utilizes the comparator to detect the output signal of the audio amplifier. Then, step 12 judges whether the output signal is greater than the critical value of the comparator. Next, step 13 outputs the driven signal when the output signal is greater than the critical value. Then, step 14 drives the clamper to output the control signal according to the driven signal. Finally, step 15 controls the audio amplifier to clamp the output signal according to the control signal.

In each of the compartmental gain limiters disclosed according to the embodiments of the invention, the input signal that does not reach the critical value is amplified according to the gain value of the audio amplifier and then an output signal is outputted to maintain the original sound field effect. When the input signal is greater than the critical value and tends to burn out the speaker, the gain value or the input signal of the audio amplifier is reduced in order to protect the speaker from burning out due to the too-large output signal.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A compartmental gain limiter to be connected to an audio amplifier having a gain value, the audio amplifier generates an output signal according to an input signal and the gain value, the compartmental gain limiter comprising:
a comparator having a critical value, the comparator receiving the output signal and outputting a driven signal when the output signal is greater than the critical value; and
a clamper for receiving the driven signal and outputting a control signal for controlling the audio amplifier according to the driven signal to clamp the output signal.

2. The compartmental gain limiter according to claim 1, wherein the control signal of the clamper controls the input signal of the audio amplifier to clamp the output signal.

3. The compartmental gain limiter according to claim 1, wherein the control signal of the clamper controls the gain value of the audio amplifier to clamp the output signal.

4. The compartmental gain limiter according to claim 1, wherein the audio amplifier is an inverting amplifier.

5. The compartmental gain limiter according to claim 4, wherein the inverting amplifier comprises:
an OP amplifier, which comprises:
an inverting input terminal;
a noninverting input terminal which is grounded; and
an output terminal;
a first resistor, which comprises:
a first terminal for receiving the input signal; and
a second terminal electrically connected to the inverting input terminal; and
a second resistor, which comprises:
a first terminal electrically connected to the second terminal of the first resistor; and
a second terminal electrically connected to the output terminal of the OP amplifier,
wherein the gain value of the inverting amplifier is determined according to the first resistor and the second resistor.

6. The compartmental gain limiter according to claim 5, wherein the control signal controls the second resistor so as to control the gain value of the audio amplifier and thus to clamp the output signal.

7. The compartmental gain limiter according to claim 5, wherein the output signal is an output voltage of the OP amplifier.

8. The compartmental gain limiter according to claim 5, wherein the output signal is a potential difference between the first terminal and the second terminal of the second resistor.

9. The compartmental gain limiter according to claim 5, wherein the output signal is a potential difference between the first terminal ad the second terminal of the first resistor.

10. The compartmental gain limiter according to claim 1, wherein the audio amplifier is a noninverting amplifier.

11. The compartmental gain limiter according to claim 10, wherein the noninverting amplifier comprises:
an OP amplifier, which comprises:
a noninverting input terminal;
an inverting input terminal; and
an output terminal;
a first resistor, which comprises:
a first terminal electrically connected to the inverting input terminal; and
a second terminal which is grounded;
a second resistor, which comprises:
a first terminal electrically connected to the inverting input terminal; and
a second terminal electrically connected to the output terminal;
a third resistor, which comprises:
a first terminal for receiving the input signal; and
a second terminal electrically connected to the noninverting input terminal; and
a fourth resistor, which comprises:
a first terminal electrically connected to the noninverting input terminal; and
a second terminal which is grounded,
wherein the gain value of the noninverting amplifier is determined according to the first resistor, the second resistor, the third resistor and the fourth resistor.

12. The compartmental gain limiter according to claim 11, wherein the control signal controls the second resistor so as to control the gain value of the audio amplifier and thus to clamp the output signal.

13. The compartmental gain limiter according to claim 11, wherein the output signal is an output voltage of the OP amplifier.

14. The compartmental gain limiter according to claim 11, wherein the output signal is a potential difference between the first terminal and the second terminal of the second resistor.

15. The compartmental gain limiter according to claim 11, wherein the output signal is a potential difference between the first terminal and the second terminal of the first resistor.

16. A method of controlling a compartmental gain limiter, which is connected to an audio amplifier and comprises a comparator and a clamper, the method comprising the steps of:
utilizing the comparator to detect an output signal of the audio amplifier;
judging whether the output signal is greater than a critical value of the comparator;
outputting a driven signal when the output signal is greater than the critical value;
driving the clamper to output a control signal according to the driven signal; and
controlling the audio amplifier to clamp the output signal according to the control signal.

17. The method according to claim 16, wherein the step of controlling the audio amplifier according to the control signal controls an input signal of the audio amplifier.

18. The method according to claim 16, wherein the step of controlling the audio amplifier according to the control signal controls a gain value of the audio amplifier.
